(19) United States
(12) Patent Application Publication
(10) Pub. No.: US 2017/0076936 A1
(43) Pub. Date: Mar. 16, 2017

(54) Method and Apparatus for Cleaning a Semiconductor Substrate

(71) Applicant: IMEC, Leuven (BE)

(72) Inventors: Paul Mertens, Bonheiden (BE); Steven Brems, Leuven (BE)

(21) Appl. No.: 15/359,355

(22) Filed: Nov. 22, 2016

Related U.S. Application Data
(62) Division of application No. 12/908,658, filed on Oct. 20, 2010.

(30) Foreign Application Priority Data
Oct. 21, 2009 (EP) 09173658.7

(51) Int. Cl. H01L 21/02; B08B 3/12; B08B 3/02; H01L 21/67

(52) U.S. Cl. CPC H01L 21/02052; H01L 21/67051; H01L 21/67057; B08B 3/12; B08B 3/02

(57) ABSTRACT

Disclosed are systems and methods for cleaning semiconductor substrates, wherein a nucleation structure having nucleation sites is mounted facing a surface of the substrate to be cleaned. The substrate and structure are brought into contact with a cleaning liquid, which is subsequently subjected to acoustic waves of a given frequency. The nucleation template features easier nucleation formation than the surface that needs to be cleaned by, for example, causing the template to have a higher contact angle when in contact with the liquid than the substrate surface to be clean. Therefore, bubbles nucleate on the structure and not on the surface to be cleaned.

### CROSS-REFERENCE TO RELATED APPLICATIONS

The present application is a divisional of U.S. patent application Ser. No. 12/908,658 filed on Oct. 20, 2010, which claims priority to European Patent Application No. 09173658.7 filed on Oct. 21, 2009, the entire contents of each of which is incorporated herein by reference.

### BACKGROUND

The present disclosure is related to a method and apparatuses for cleaning a substrate, in particular a semiconductor substrate, by bringing the substrate in contact with a cleaning fluid and applying acoustic energy to the fluid.

Ultrasonic and megasonic wafer cleaning methods are known in the semiconductor industry, in particular for cleaning silicon wafers. The general principle is to bring the wafer into contact with a cleaning liquid, usually by submerging the wafer in a liquid-filled tank, and to apply acoustic energy to the cleaning liquid, by way of an electromechanical transducer. Most known applications use acoustic waves in the ultrasonic (<200 kHz) or megasonic (up to or above 1 MHz) frequency range. The acoustic energy causes cavitation, i.e. the creation of bubbles that oscillate or even collapse. The bubbles assist in the removal of particles from the wafer surface, due to the drag forces created by the bubble formation or the bubble oscillation, or by drag forces created when bubbles become unstable and collapse. However, current techniques suffer from a number of problems. At ultrasonic frequencies, bubbles tend to be large and collapse more heavily, leading to an increased risk of damaging the substrate and the structures present on it. Megasonic cleaning leads to smaller bubbles and lower damage risk. However, as the structures present in integrated circuits are made smaller each new generation of technology, the damage risk remains. On the other hand, when the bubbles are too small, they do not sufficiently contribute to the removal of particles from the wafer surface.

### SUMMARY

This disclosure aims to propose a method and apparatus for cleaning a semiconductor substrate by the action of cavitation bubbles under the influence of acoustic energy, wherein the risk of damaging the substrate is reduced, whilst ensuring a good particle removing capability.

The disclosure is related to an apparatus for cleaning one or more semiconductor substrates, comprising: a means for holding a substrate having a surface to be cleaned; a nucleation structure, comprising a nucleation surface having nucleation sites for bubble formation when in contact with a cleaning liquid; a means for mounting said nucleation structure with its nucleation surface facing said surface to be cleaned; a means for supplying a cleaning liquid to as to substantially fill the space between the surface to be cleaned and the nucleation surface; and a means for subjecting said liquid, while present in said space, to an oscillating acoustic force.

Preferably, when the apparatus is used in combination with a particular cleaning liquid, at least the nucleation sites exhibit a higher contact angle with said cleaning liquid than the surface to be cleaned. When the cleaning liquid is water, the nucleation sites preferably have a higher hydrophobicity than the surface to be cleaned. The material of the nucleation structure may be non-porous or porous with respect to the cleaning liquid. The nucleation structure may be a porous substrate wherein the pores at the surface of the substrate form said nucleation sites.

According to an embodiment, the nucleation structure is a nucleation substrate, hereinafter called a ‘template’, having a front and back side, the nucleation surface being on the front side, the nucleation surface comprising a pattern of cavities, the cavities forming bubble nucleation sites.

The template may comprises an electrode, the electrode forming the bottom of said cavities or being electrically connected to the bottom of said cavities, and wherein the apparatus further includes a voltage source or means to connect the apparatus to a voltage source, so as to apply a voltage difference between the electrode and the surface to be cleaned, while the space is filed by said liquid.

According to an embodiment, the nucleation structure includes channels, each channel extending between the back of the template and the bottom of one of said cavities, the apparatus further including a supply means for supplying a gaseous substance, so that the substance flows from the back of the template, through the channels, and to the cavities, while the space is filled by said liquid.

According to another embodiment, the nucleation structure is a membrane having pores or openings configured to act as nucleation sites.

According to one embodiment, an apparatus according comprises: a tank which can be filled with the cleaning liquid; a means for mounting said substrate and the nucleation structure in the tank; and a transducer arranged on the underside or on a side wall of the tank, for producing the acoustic force.

According to another embodiment, an apparatus according comprises: means for holding a single substrate, having a surface to be cleaned; a supply means for supplying cleaning liquid onto the surface to be cleaned; a means for mounting the nucleation structure so that a liquid film may be formed between the nucleation surface and the surface to be cleaned; and a transducer arranged in contact with the nucleation structure, for producing the acoustic force.

The apparatus according to the latter embodiment may further comprise a rotatable holder for the substrate to be cleaned, so as to rotate the substrate around its central axis perpendicular to the surface to be cleaned, and said supply means may be arranged to supply liquid to the surface to be cleaned while the substrate is rotating.

In an apparatus according to one embodiment, the nucleation structure may be configured to remain stationary with respect to the substrate, while the substrate is subjected to the acoustic force.

An apparatus according to one embodiment may further comprise a means for moving the nucleation structure with respect to the substrate, while the liquid is subjected to the acoustic force.

Also disclosed is a method for cleaning a semiconductor substrate with a cleaning liquid, the method comprising: providing and holding a substrate comprising a surface to be cleaned; providing a nucleation structure comprising a nucleation surface having nucleation sites for bubble formation when in contact with said cleaning liquid; mounting the nucleation structure so that the nucleation surface is facing the surface to be cleaned; bringing the nucleation surface and the surface to be cleaned into contact with the cleaning liquid, by substantially filling the space between the substrate and the nucleation surface; and subjecting said cleaning liquid to an oscillating acoustic force, thereby obtaining bubbles in said liquid, said bubbles nucleating on the surface of the nucleation structure, and the bubbles causing drag forces acting on the surface to be cleaned.

In an embodiment of the method, at least the nucleation sites exhibit a higher contact angle when in contact with said liquid than the surface to be cleaned.

According to an embodiment, the substrate to be cleaned and the nucleation structure are submerged in a tank filled with the cleaning liquid, before subjecting the liquid to the acoustic force.

According to another embodiment, the acoustic forces are produced by a transducer so as to produce acoustic waves propagating through the liquid in a propagating direction perpendicular to a transducer surface, and the substrate and nucleation structure are placed at an angle with respect to the propagation direction, the angle being chosen so as to maximize the transmission of acoustic energy through the substrate to be cleaned.

According to an embodiment of the method, the nucleation structure is arranged in proximity to the surface to be cleaned, and wherein a film of the cleaning liquid is formed between the nucleation structure and the surface to be cleaned.

### BRIEF DESCRIPTION OF THE DRAWINGS

FIG. 1 shows a cleaning apparatus according to a first embodiment.

FIG. 2 illustrates the cleaning mechanism in an apparatus according to an embodiment.

FIG. 3 shows an apparatus according to an embodiment, having a bubble nucleation membrane.

FIG. 4 illustrates the bubble formation using a nucleation membrane.

FIG. 5 shows an apparatus according to an embodiment, having a movable bubble nucleation structure.

FIG. 6 shows an apparatus having a nucleation structure comprising an electrode.

FIG. 7 shows an apparatus according to an embodiment, wherein the substrate and the nucleation structure are mounted at an angle.

FIG. 8 illustrates the relation between the orientation of a substrate and the acoustic reflectivity coefficient.

FIG. 9 shows an apparatus according to another embodiment, involving the formation of a film of liquid on a substrate to be cleaned.

FIG. 10 shows an apparatus according to an embodiment, involving microchannels formed in a nucleation structure.

### DETAILED DESCRIPTION

In a method and apparatus in accordance with an embodiment, a substrate is brought into contact with a cleaning liquid, e.g. submerged in a tank containing said cleaning liquid, and an oscillating acoustic force is applied to the liquid, in a manner known in the art, sending acoustic waves through the liquid. Characteristic to the embodiment is the presence of a nucleation structure, comprising a nucleation surface facing (preferably parallel to) the surface to be cleaned, said nucleation surface comprising nucleation sites for the formation of cavitation bubbles under the influence of the acoustic waves travelling through the liquid. Nucleation sites are locations which exhibit an increased affinity for bubble formation due to the topography of the surface, e.g. as a consequence of holes or pores, as will be explained on the basis of the embodiments described hereafter. Preferably, the material of the nucleation surface or at least of those parts of the surface corresponding to the nucleation sites, exhibit(s) a higher contact angle when in contact with the cleaning liquid than the substrate surface. When the cleaning liquid is water, this means that the structure is more hydrophobic than the substrate.

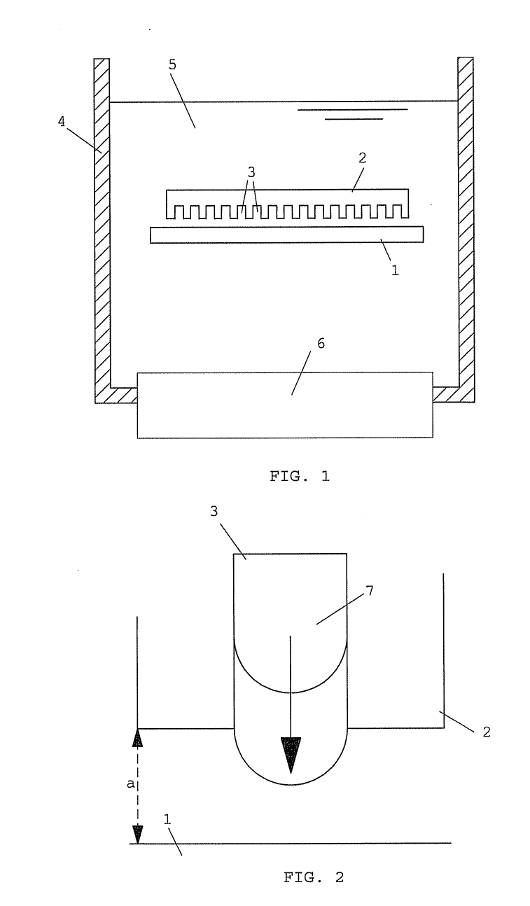

FIG. 1 shows a first embodiment, where the structure is provided in the form of a ‘bubble template’ 2, which is a patterned substrate placed in close vicinity and substantially parallel to the substrate 1 to be cleaned. The pattern consists of a plurality of small cavities 3, obtained for example by etching, in the template's surface, said cavities serving as nucleation sites for the bubble formation. The cavities 3 may be present over the totality of or on a portion of the template surface. The template 2 is held at a fixed distance to the substrate by appropriate holding means (not shown). In the embodiment of FIG. 1, the substrate-template assembly is mounted in a tank 4, which can be filled with a cleaning liquid 5, and wherein an electromechanical transducer 6 is attached to the bottom of the tank. The transducer 6 can also be attached to the side of the tank, submerged in the tank, or directly connected to template 2. A transducer can be used of a type known in the art, for example as described in patent documents U.S. Pat. No. 6,904,921 or U.S. Pat. No. 5,355,048.

The amount by which the pressure increases (or decreases) in the cleaning liquid as a sound wave travels through it is called pressure amplitude. The pressure amplitude of the acoustic waves may be situated in a range which causes transient cavitation, i.e. wherein bubbles grow to their maximum size and collapse at a certain distance from the substrate surface, thereby causing a strong microscopic streaming which results in drag forces working on the substrate surface. Simulations indicate that in the case of oxygen bubbles in water, when a pressure amplitude of 3 bar is applied at a frequency of 1 MHz, the bubbles with an initial diameter of about 500 nm in diameter grow to about 3.5 micron in diameter before collapsing. Alternatively, the pressure amplitude may be lower so that a stable oscillating bubble formation is obtained: bubbles growing from a minimum to a maximum size and back, at the frequency of the applied acoustic force.

FIG. 2 illustrates the way in which the cleaning takes place: bubbles 7 are present in the cavities or nucleate on the template 2 and not on the substrate 1, due to the presence of the nucleation sites. The bubble formation on the template 2 is further enhanced when there is a difference in (hydro)phobicity. Transient bubble behaviour induces strong microscopic streaming which results in drag forces working on the substrate surface. Because the bubbles are nucleated on the template 2, the majority of the bubbles do not collapse onto the substrate 1, thereby reducing the risk of damaging the substrate 1. In this way it becomes possible to apply higher acoustic forces/energies, able to remove particles effectively, without damaging the substrate surface. When a stable oscillating bubble regime is obtained (not transient) on the template 2, the drag forces working on the substrate 1 to be cleaned are reduced as a result of the distance between the bubble and the substrate surface, so that a higher amplitude/energy may be applied without damaging the substrate 1.

The distance “a” (in FIG. 2) between the template 2 and the substrate 1 is in the order of 1 to a few 100 of micrometers, depending on the maximum size of the bubbles. It is preferred that said distance is about one to ten times the maximum bubble diameter. This also makes it possible to adjust the drag forces by adjusting the distance a. The maximum bubble size depends on the pressure amplitude and frequency. The value of the distance a defines, at least in part, a resonance frequency at which the bubbles reach the highest maximum size before collapsing. It is a preferred mode of operation to work within such a resonance regime in order to maximize the cleaning effect, even though the embodiments are not limited to such a mode of operation.

The size of the cavities 3 is not drawn on a realistic scale in FIG. 1, nor is the shape of the cavities 3 limited to the embodiment illustrated in FIG. 1. The cavities 3 may, alternatively or additionally, have the shape of a truncated cone, a cylinder, a truncated pyramid, or a prism. The material and shape are optimized to act as efficient nucleation sites for bubbles to be created. The cavities 3 may have a circular cross-section having a diameter in the order of nanometers (nm) or micrometers (□m) depending on the size of bubbles which are being produced and the pressure amplitudes that are applied. For example, holes with a 4 □m diameter can be used in combination with a 1 MHz acoustic force at an amplitude of 3 bar. The distance between holes on the template surface may vary between the cavity diameter and ˜10 times the bubble radius.

The template 2 is an example of the nucleation structure referred to in appended claim 1. Instead of a patterned substrate 1, any structure can be used having a surface comprising nucleation sites for bubble formation. For example, a substrate with a surface having a high roughness (for example a black Si substrate) can be used given that the peaks and troughs of the roughness profile also constitute nucleation sites. Moreover, it has been proven that a considerable roughness in itself renders a surface more (hydro)phobic compared to a smooth surface. Besides a solid substrate, a substrate may be used provided with a layer having a suitable roughness, for example a Si-substrate provided with a layer of porous low-K dielectric material.

The material from which the nucleation structure is made can be a non-porous material, i.e. non-porous for the cleaning liquid. Alternatively, the nucleation structure can be made from a porous material, for example porous Teflon. A porous material will allow more liquid to enter the space between the template 2 and the substrate 1 when the substrate 1 and template 2 are submerged in the liquid 5, thereby ensuring a steady bubble formation. Also dissolved gas, expected to assist bubble formation, can be supplied through the porous material. When a porous material is used, the pores which are located at the surface of the structure may themselves constitute nucleation sites, i.e. a porous nucleation structure may take on the form of a flat substrate (not provided with a pattern of cavities), and wherein the pores themselves are forming bubble nucleation sites.

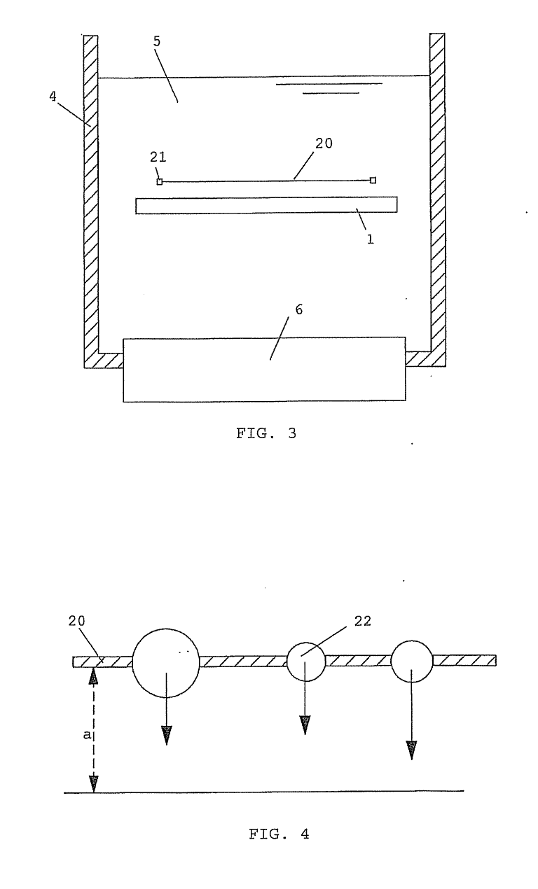

The nucleation structure may be a porous membrane instead of a solid structure, see FIG. 3, which shows a membrane 20 mounted in a frame 21. With porous membrane is meant a thin layer of a material with openings throughout the thickness of the layer. It may be a membrane 20 made from a porous material, wherein the openings are a consequence of the porosity of the material, or a membrane 20 provided with a net-like pattern of openings. The openings serve as nucleation sites for bubble formation, as illustrated in FIG. 4. A GORE™ membrane could be suitable for use in the present embodiment.

The template 2 (or any nucleation structure) may be stationary with respect to the substrate 1, or may be movable. A stationary template may have a surface which is smaller, equal or larger than the substrate surface. In one case, the template has a circular surface, placed concentrically with the surface of a round wafer. The surface of a movable template may be smaller than the substrate surface, see FIG. 5. It is configured in cooperation with a drive means 8 to move the template 2 over the surface of the substrate 1, preferably whilst remaining parallel to the substrate surface.

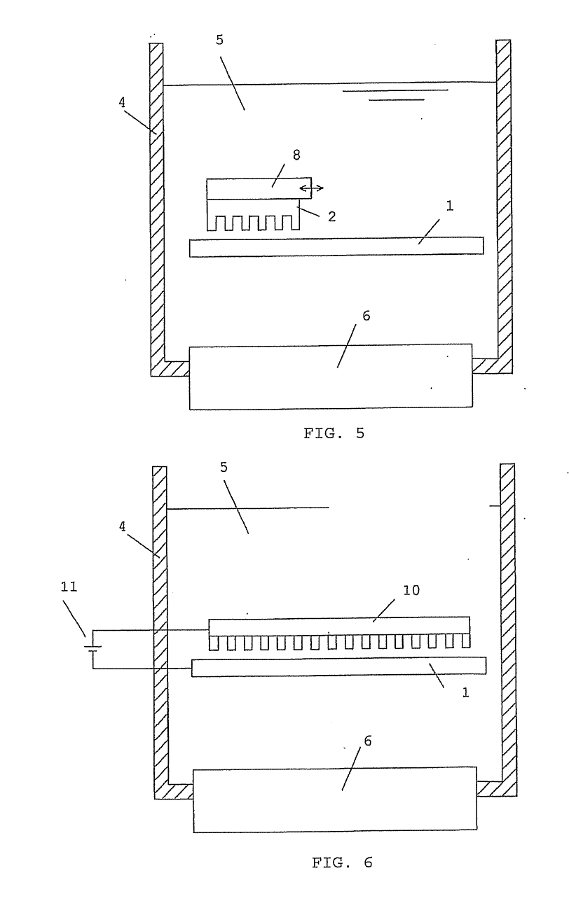

According to another embodiment, the nucleation structure may be a bubble template as shown in FIG. 6, comprising an electrode 10, and wherein the bottom of the bubble nucleation cavities is formed by said electrode 10. When the electrode 10 and the substrate 1 are coupled to an electric power source 11 while being submerged in the cleaning liquid 5 having an appropriate composition, electrolysis takes place so that gas bubbles are produced in the cavities. In this way, bubble formation is facilitated as gas bubbles are generated in situ.

Another way of obtaining in-situ gas generation is by choosing a cleaning solution with a composition comprising reactive components. For example, in a solution comprising NH₄OH and H₂O₂, these elements will react to form NH₃ and O₂ in gaseous form. This reaction will thus generate gas bubbles in the cleaning liquid 5. In order to enhance such reactions, the bottom and possibly also the sidewalls of the cavities may be provided with a catalyst for the reaction in question. The catalyst may be applied in the form of a coating. For example, a manganesedioxide coating serves as a catalyst for the decomposition of H₂O₂ in H₂O and O₂.

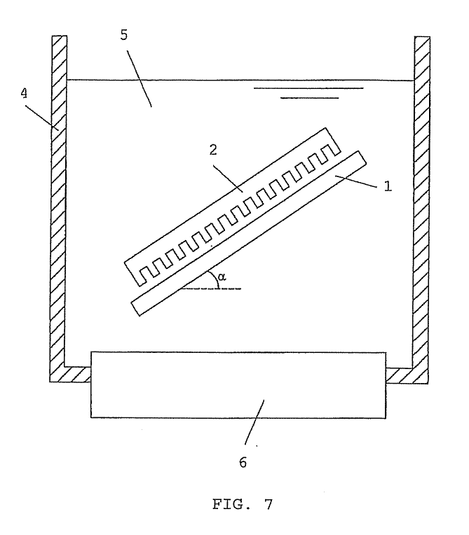

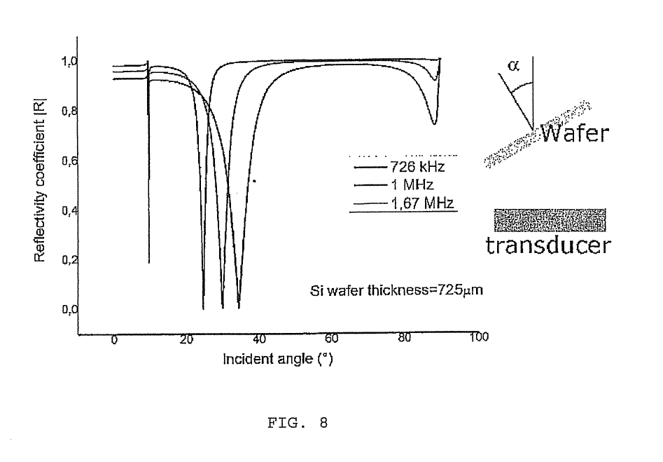

FIG. 7 shows an embodiment wherein the substrate 1 and template 2 are positioned at an angle □ with respect to the transducer surface, i.e. the surface which is perpendicular to the propagation direction of the acoustic waves produced by the transducer 6. It has been shown that the acoustic reflection characteristics of a thin silicon substrate, here referred to as a wafer, are highly dependent on the orientation of the wafer with respect to the propagation direction of acoustic waves. As seen in FIG. 8, a sharp drop in reflectivity coefficient is observed, and thus a peak in transmission of acoustic energy through the Si-wafer, depending on the frequency of the applied waves. The position of the peak is further dependent on the wafer thickness, the acoustic impedances of the wafer and the cleaning liquid, said impedances being themselves dependent on the angle of incidence, density, Young's modulus, and Poisson's ratio. Based on this knowledge, it is advantageous to place the substrate 1 and template 2 under an angle corresponding to the transmission peak, so that a maximum of acoustic energy reaches the space between the Si-wafer and the template.

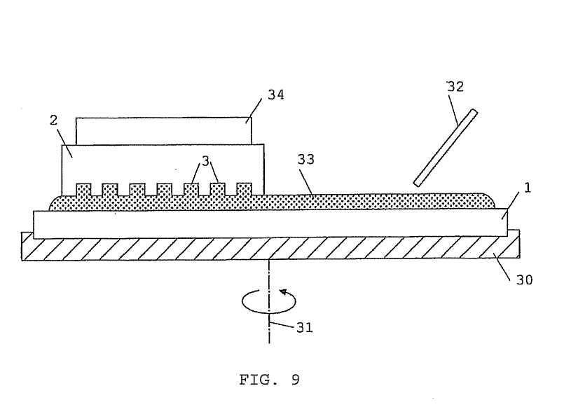

The above methods have been described in combination with an apparatus wherein a substrate 1 is submerged in a tank 4 filled with a cleaning liquid 5. According to another embodiment, the contact between the nucleation structure and the substrate on the one hand and the cleaning liquid on the other hand is obtained by providing a film of liquid between the nucleation structure and the substrate. Any of the nucleation structures described above can be applied in this embodiment. FIG. 9 shows the case wherein a nucleation template 2 is used, i.e. a substrate provided with a pattern of cavities 3 on the surface. The substrate 1 is mounted in a substrate holder 30, arranged to hold the substrate 1 firmly in place and further arranged to rotate the substrate 1 around a central rotation axis 31. Any suitable type of rotatable substrate holder known in the art may be used for this purpose. A cleaning liquid supply means, such as a nozzle 32, is provided for supplying liquid to the surface of the substrate 1. The nucleation template 2 is arranged in close proximity and substantially parallel to the substrate surface, at a distance to the surface which allows the build-up of a film 33 of liquid between the substrate 1 and the template 2. The template 2 is preferably stationary but may also be movable in a direction parallel to the substrate surface. The template 2 may have any suitable shape, e.g. it may be in the shape of a beam or arm arranged parallel to the substrate surface. The rotation of the substrate 1 causes liquid to flow off the substrate 1, while fresh liquid is supplied via the liquid supply nozzle 32. An electromechanical transducer 34 is attached to the template 2, to cause acoustic waves of a given frequency to appear in the liquid film. The generation of bubbles and the cleaning action caused by said bubbles takes place as in the embodiment(s) described above.

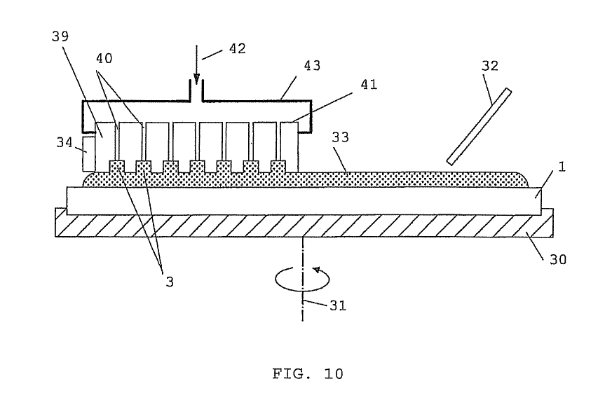

According to another embodiment, illustrated in FIG. 10, the nucleation structure 39 is a substrate, for example a patterned substrate provided with a pattern of cavities 3 as described above, and further provided with a plurality of channels 40 connecting the back surface 41 of the nucleation structure to the bottom of the holes. Channels 40, also referred to as microchannels, may be of a diameter smaller than the diameter of the cavities 3, as shown, or they may have a diameter larger than the cavities, or corresponding to the cavities, in which case the microchannels run throughout the thickness of the template. The microchannels are further connected to a supply 42 of a gaseous substance, thereby directing a gas flow towards the bottom of the holes, while the nucleation surface is in contact with a cleaning liquid. In the embodiment shown in FIG. 10, the cleaning liquid is present as a liquid film, as already described in relation to FIG. 9. A gas supply collector 43 may be applied in order to guide the gas supply towards the microchannels. The gas supply greatly enhances the formation of gas bubbles at the bottom of the holes, the bubbles developing further under the influence of an acoustic force, generated by an electromechanical transducer 34 attached to the nucleation structure 39. This embodiment can also be used in combination with a tank filled with a cleaning liquid, provided that appropriate measures are taken to bring the gas supply to the microchannels while the substrate 1 and nucleation structure 39 are submerged in a liquid.

What is claimed is:

1. A method for cleaning a semiconductor substrate with a cleaning liquid, comprising:
mounting a substrate comprising a surface to be cleaned;
mounting a nucleation structure comprising a nucleation surface having nucleation sites for bubble formation when in contact with the cleaning liquid, such that the nucleation surface is facing the surface to be cleaned;
bringing the nucleation surface and the surface to be cleaned into contact with the cleaning liquid by substantially filling a space between the substrate and the nucleation surface; and
subjecting the cleaning liquid to an oscillating acoustic force, thereby obtaining cavitation bubbles in the liquid, the bubbles nucleating on the surface of the nucleation structure, and the bubbles causing drag forces acting on the surface to be cleaned.

2. The method according to claim 1, wherein at least the nucleation sites exhibit a higher contact angle when in contact with the liquid than the surface to be cleaned.

3. The method according to claim 1, wherein the surface to be cleaned and the nucleation surface are submerged in the cleaning liquid.

4. The method according to claim 3, wherein the acoustic force is produced by a transducer so as to produce acoustic waves propagating through the liquid in a propagation direction perpendicular to a transducer surface, and wherein the surface to be cleaned and the nucleation surface are placed at a non-zero angle with respect to the propagation direction, the angle being chosen so as to maximize the transmission of acoustic energy through the substrate to be cleaned.

5. The method according to claim 1, wherein the nucleation surface is arranged in proximity to the surface to be cleaned, and wherein a film of the cleaning liquid is formed between the nucleation surface and the surface to be cleaned.

6. The method according to claim 1, further comprising applying a voltage difference between the nucleation structure and the surface to be cleaned.

7. The method according to claim 1, further comprising supplying a gaseous substance through channels formed in the nucleation structure.

8. The method according to claim 1, further comprising moving the nucleation structure with respect to the substrate while the liquid is subjected to the acoustic force.

9. The method according to claim 8, wherein moving the nucleation structure with respect to the substrate includes moving the nucleation structure in a direction parallel to the surface to be cleaned.

10. The method according to claim 1, wherein the nucleation surface includes cavities that form the nucleation sites, wherein one or more of the cavities have a diameter of 4 micrometers, and wherein the oscillating acoustic force is a 1 MHz acoustic force at an amplitude of 3 bar.

11. The method according to claim 1, wherein mounting the nucleation structure includes positioning the nucleation surface between 1 micrometer and 100 micrometers of the surface to be cleaned.

12. A method for cleaning a semiconductor substrate with a cleaning liquid, comprising:
providing a substrate comprising a surface to be cleaned;
providing a nucleation structure comprising a nucleation surface such that the nucleation surface is facing the surface to be cleaned, wherein the nucleation surface includes a plurality of cavities having open front surfaces, wherein the plurality of cavities are configured to form bubble nucleation sites for cavitation bubble formation when an oscillating acoustic force is applied to the cleaning liquid in contact with the nucleation surface;
bringing the nucleation surface and the surface to be cleaned into contact with the cleaning liquid by substantially filling a space between the substrate and the nucleation surface with the cleaning liquid; and
subjecting the cleaning liquid to the oscillating acoustic force, thereby obtaining cavitation bubbles in the liquid, the cavitation bubbles nucleating at the nucleation sites, and the bubbles causing drag forces acting on the surface to be cleaned.

13. The method according to claim 12, wherein each of the plurality of cavities has a closed back surface.

14. The method according to claim 12, wherein the cavities have a diameter of 4 micrometers, and wherein the oscillating acoustic force is a 1 MHz acoustic force at an amplitude of 3 bar.

15. The method according to claim 12, wherein providing the nucleation structure includes positioning the nucleation surface between 1 micrometer and 100 micrometers of the surface to be cleaned.

16. The method according to claim 12, wherein the surface to be cleaned and the nucleation surface are submerged in the cleaning liquid, wherein the acoustic force is produced by a transducer so as to produce acoustic waves propagating through the liquid in a propagation direction perpendicular to a transducer surface, and wherein the surface to be cleaned and the nucleation surface are placed at a non-zero angle with respect to the propagation direction.

17. The method according to claim 12, further comprising applying a voltage difference between the nucleation surface and the surface to be cleaned.

18. The method according to claim 12, further comprising supplying a gaseous substance through channels formed in the nucleation structure and to the cavities.

19. The method according to claim 12, further comprising moving the nucleation structure with respect to the substrate in a direction parallel to the surface to be cleaned.

20. The method according to claim 1, wherein the nucleation surface is arranged in proximity to the surface to be cleaned, and wherein a film of the cleaning liquid is formed between the nucleation surface and the surface to be cleaned.
